(19) United States
(12) Patent Application Publication
(10) Pub. No.: US 2007/0125837 A1
(43) Pub. Date: Jun. 7, 2007

(54) Method for processing reception call in mobile RFID service, and a wireless communication terminal employing the same

(76) Inventors: Chan-Won Park, Daejon (KR); Mal-Hee Kim, Daejon (KR); Myung-Hee Son, Daejon (KR); Gil-Young Choi, Daejon (KR); Cheol-Sig Pyo, Daejon (KR); Jong-Suk Chae, Daejon (KR); Joo-Moon Lee, Daejon (KR); Gene-Hee Yoon, Daejon (KR); Taejeen Shin, Syosset, NY (US)

Correspondence Address: LADAS & PARRY LLP, 224 SOUTH MICHIGAN AVENUE, SUITE 1600, CHICAGO, IL, 60604, US

(21) Appl. No.: 11/607,784

(22) Filed: Nov. 29, 2006

(30) Foreign Application Priority Data
Dec. 1, 2005 (KR) 10-2005-0116124
May 11, 2006 (KR) 10-2006-0042577

(51) Int. Cl. G06F 17/00; H04Q 5/22; H05K 11/00; G08B 13/14

(52) U.S. Cl. 235/375; 340/572.1; 340/10.1; 455/344

(57) ABSTRACT

Provided are a method for processing reception calls during mobile RFID service processing, and a wireless terminal employing the method. The terminal provides mobile RFID service by receiving tag information from the RFID reader, requesting the object directory server for CS position information based on the tag information, requesting service contents based on the tag information and CS position information. The present invention prevents collision between reception call processing and mobile RFID service processing in the wireless terminal by processing reception call appropriately to each duration of mobile RFID service processing. For example, when a call is received before read command is transmitted to the RFID reader, the RFID reader is turned off and the reception call is processed. When a call is received before CS position information is requested, the CS position information is requested after the reception call is processed.

### FIELD OF THE INVENTION

The present invention relates to a method for processing a reception call in a mobile radio frequency identification (RFID) service, and a wireless communication terminal employing the method; and, more particularly, to a method for effectively processing a reception call in the middle of using a mobile RFID service, which is the first step to be processed when a mobile RFID service system is combined with a mobile communication network, and a wireless communication terminal employing the method.

### DESCRIPTION OF RELATED ART

Generally, Radio Frequency Identification (RFID) is a technology for recognizing, tracing, and managing human beings, animals, and/or objects with a tag attached thereto by writing or reading information in or out of a tag having its own identification information without a contact. An RFID system includes a plurality of electronic tags, or a transponder, which will be simply referred to as tags hereinafter, and an RFID reader, or an interrogator. Each tag has identification information and it is attached to an object or an animal, and the RFID reader writes or reads information in or out of the tags. RFID systems are divided into a mutual induction type and an electromagnetic wave type according to the communication method between the RFID reader and the tags. The RFID systems are also divided into an active type and a passive type according to whether the tags are operated with their own power source. They are also divided into a long wavelength RFID reader, an intermediate wavelength RFID reader, a short wavelength RFID reader, an ultra short wavelength RFID reader, and a microwave RFID reader. Diverse specifications are defined or under a definition process according to the above classification.

Meanwhile, a Ubiquitous Sensor Network (USN) connects and manages RFID tags in all places where data need to be collected in real-time and collects not only recognition information of objects having the tags attached thereto but also environmental information of the tags. Ultimately, the ubiquitous sensor network realizes a communication environment any time any place by giving computing and communication functions to all objects, regardless of the kinds of networks, devices, and services.

There is an attempt to connect the RFID system composed of RFID readers and tags to a commercial mobile communication network to promote the use of RFID technology in more diverse fields and activate the RFID system. To connect the RFID system with the commercial mobile communication network, researchers are studying to build an RFID reader module in the inside of a wireless communication terminal or connect an RFID reader module to the wireless communication terminal as an additional device.

According to conventional technologies, connection between an RFID reader and a wireless communication terminal signifies no more than a simple display of an RFID reader operation result on a display of the wireless communication terminal. Also, when the wireless communication terminal equipped with the RFID reader module is to provide a mobile RFID service through a mobile communication network and/or the Internet, there is a shortcoming that the RFID function of the wireless communication terminal collides with the existing communication function. Therefore, it is required to develop a technology that can process calls without collision when a call is received during the mobile RFID service to smoothly provide the mobile RFID service through a wireless communication terminal.

### SUMMARY OF THE INVENTION

It is, therefore, an object of the present invention to provide a method for effectively processing a reception call in the middle of using a mobile RFID service, which is the first step to be processed when a mobile RFID service system is combined with a mobile communication network, and a wireless communication terminal employing the method.

It is another object of the present invention to provide a method for processing a reception call appropriately for each step of a mobile RFID service, and a wireless communication terminal employing the method.

Particularly, the present invention aims to resolving a problem of collision between a reception call process and a mobile RFID service process, when a wireless communication terminal receives a call in the middle of using the mobile RFID service.

Other objects and advantages of the present invention can be understood by the following description, and become apparent with reference to the embodiments of the present invention. Also, it is obvious to those skilled in the art to which the present invention pertains that the objects and advantages of the present invention can be realized by the means as claimed and combinations thereof.

In accordance with an aspect of the present invention, there is provided a wireless communication terminal capable of providing a mobile radio frequency identification (RFID) service, which includes: an RFID reader configured to acquire tag information through communication with an RFID tag; a controller configured to request an object directory server (ODS) for contents server (CS) position information based on the tag information transmitted from the RFID reader and request a contents server for service contents information based on the tag information and the CS position information transmitted from the object directory server; and a terminal memory configured to store the tag information, wherein the controller performs control to avoid collision between a reception call processing and a mobile RFID service processing according to when a call is received in the steps of the mobile RFID service processing.

To be specific, when a call is received before the controller transmits a read command for initiating communication with the RFID tag to the RFID reader, the controller turns off power applied to the RFID reader and engages in the reception call processing. Also, when the call is received before the controller receives the tag information from the RFID reader which has received the read command for initiating communication with the RFID tag, the controller receives the tag information from the RFID reader after processing the reception call. The RFID reader includes a reader memory configured to store tag information, which is acquired from the communication with the RFID tag.

Also, when a call is received before the controller requests the object directory server for CS position information based on the tag information transmitted from the RFID reader, the controller processes the reception call and then requests the object directory server for the CS position information. Also, when a call is received before the controller receives service contents information from the contents server after requesting the object directory server for the CS position information, the controller executes an operation selected by a terminal user between the reception call processing and the mobile RFID service processing. When a call is received before the controller receives service contents information from the contents server after requesting the object directory server for the CS position information, the controller may terminate the mobile RFID service and then engage in the reception call processing. Also, when a call is received after the controller receives CS position information from the object directory server, the controller may store the received CS position information in the terminal memory and terminate the mobile RFID service processing. In this case, the controller processes the reception call and then resumes the mobile RFID service processing from the step of requesting the contents server for service contents information. Finally, when a call is received after the controller receives service contents information from the contents server, the controller stores the received service contents information in the terminal memory and processes the reception call.

In accordance with another aspect of the present invention, there is provided a method for processing a reception call in a wireless communication terminal while processing a mobile RFID service, which includes the steps: a) acquiring tag information through communication between an RFID reader and a RFID tag; b) requesting an object directory server for CS position information based on the tag information; and c) requesting a contents server for service contents information based on the CS position information transmitted from the object directory server and the tag information, wherein when a call is received before the CS position information is requested to the object directory server based on the tag information, the CS position information is requested after reception call processing is terminated.

When a call is received before the CS position-information is requested to the object directory server based on the tag information, the reception call processing is executed through the steps of: e) storing the tag information in a terminal memory of the wireless communication terminal; and f) requesting the object directory server for the CS position information based on the tag information stored the terminal memory after the reception call processing is terminated. Meanwhile, when the call is received before a read command for initiating the communication between the RFID reader and the RFID tag is transmitted to the RFID reader, power supplied to the RFID reader is turned off and then the reception call is processed.

Also, when a call is received before the tag information is transmitted from the RFID reader which has received the read command for initiating the communication with the RFID tag, the reception call is processed and then the tag information is transmitted from the RFID reader. Also, when a call is received before the tag information is transmitted from the RFID reader which has received the read command for initiating the communication with the RFID tag, the reception call is processed through the steps of: g) transmitting a call reception notification signal for informing the reception of a call from a controller of the wireless communication terminal to the RFID reader; h) storing the tag information acquired from the communication between the RFID reader and the RFID tag in a reader memory of the RFID reader; i) transmitting a call processing termination notification signal for informing that the reception call processing is terminated from the controller to the RFID reader; and j) transmitting the tag information stored in the reader memory of the RFID reader to the controller.

Meanwhile, when a call is received before the service contents information is transmitted from the contents server after CS position information is requested to the object directory server, any one between the reception call processing and the mobile RFID service processing may be selected by a terminal user and executed, or the mobile RFID service processing may be suspended and the reception call processing is executed. When the mobile RFID service processing is suspended and the reception call is processed, the reception call processing is executed through the steps of: k) storing the tag information transmitted from the RFID reader in a terminal memory of the wireless communication terminal; and l) requesting the object directory server for CS position information based on the tag information stored in the terminal memory after the reception call processing is terminated.

Meanwhile, when a call is received after the CS position information is transmitted from the object directory server, the CS position information is stored in the terminal memory of the wireless communication terminal and the mobile RFID service processing is suspended. In this case, service contents information is requested to the contents server based on the tag information and the CS position information stored in the terminal memory after the reception call processing is terminated. Finally, when a call is received after the service contents information is transmitted from the contents server, the service contents information is stored in the terminal memory of the wireless communication terminal and then the reception call is processed.

### BRIEF DESCRIPTION OF THE DRAWINGS

The above and other objects and features of the present invention will become apparent from the following description of the preferred embodiments given in conjunction with the accompanying drawings, in which:

FIG. 1 is a block view showing a mobile radio frequency identification (RFID) service system;

FIG. 2 is a block view showing a structure of a wireless communication terminal equipped with a mobile RFID reader in accordance with an embodiment of the present invention;

FIG. 3 is a flowchart describing an operation of a wireless communication terminal for a mobile RFID service;

FIG. 4 is a view illustrating a method of processing a reception call according to when the call is received in the steps of a mobile RFID service processing which is divided into five durations in accordance with an embodiment of the present invention.

FIG. 5 is a flowchart describing a call reception process when a controller does not receive tag information after a read command in accordance with an embodiment of the present invention; and

FIG. 6 is a flowchart describing a call reception process when the controller does not receive RFID service contents information after requesting for contents server (CS) position information in accordance with an embodiment of the present invention.

### DETAILED DESCRIPTION OF THE INVENTION

Other objects and aspects of the invention will become apparent from the following description of the embodiments with reference to the accompanying drawings, which is set forth hereinafter. When it is considered that detailed description on a related art may obscure the points of the present invention, the description will not be provided herein. Hereinafter, preferred embodiments of the present invention will be described in detail with reference to the accompanying drawings.

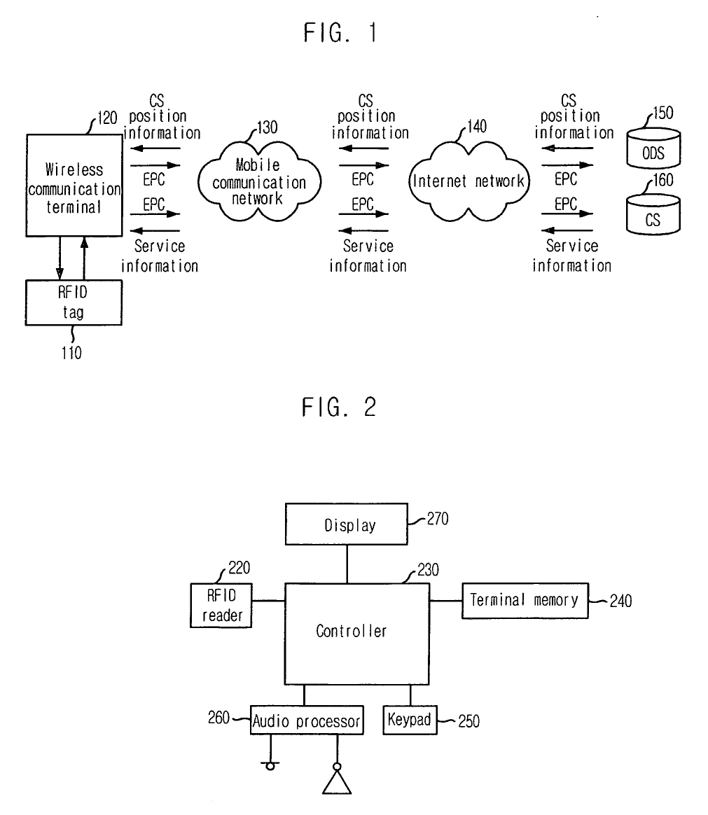

FIG. 1 is a block view showing a mobile radio frequency identification (RFID) service system. FIG. 2 is a block view showing a structure of a wireless communication terminal equipped with a mobile RFID reader in accordance with an embodiment of the present invention.

Referring to FIG. 1, the mobile RFID service system includes an RFID tag 110, a wireless communication terminal 120, a mobile communication network 130, an Internet network 140, an object directory server (ODS) 150, and a contents server (CS) 160. The object directory server 150 stores position information of the contents server 160 including contents information on an Electronic Product Code (EPC) code, and the contents server 160 stores service contents information on a corresponding EPC code.

Meanwhile, as shown in FIG. 2, the wireless communication terminal 120 includes an RFID reader 220, a controller 230, a terminal memory 240, a keypad 250, an audio processor 260, and a display 270. The RFID reader 220 may be mounded in the inside of a terminal such as a mobile phone, a personal digital assistant (PDA), and a smart phone, or it may be detachably attached to the terminal in the form of a module such as a PCMICA.

The controller 230 not only performs a conventional call processing but also performs a function of connecting the object directory server 150 and the contents server 160. To be specific, the controller 230 extracts significant information from tag information transmitted from the RFID reader, processes data for requesting for CS position information, and processes data for requesting for contents information by using the CS position information and the tag information.

Hereinafter, a mobile RFID service system and operation of a wireless communication terminal equipped with a mobile RFID reader will be described with reference to FIGS. 1 and 2.

First, when a terminal user selects an RFID menu on a Graphical User Interface (GUI) through the keypad 250, the controller 230 transmits a waiting command to the RFID reader 220. The RFID reader 220 which has received the waiting command notifies the controller 230 that its mode is switched into a waiting mode and maintains the waiting mode until it receives a read command from the controller 230.

When the user brings about the RFID reader 220 close to a tag attached to an object of an interest and selects a mobile RFID service through the keypad 250, the controller 230 transmits a read command to the RFID reader 220. Upon receipt of the read command, the RFID reader 220 communicates with the RFID tag 110, which is called a reader-to-tag communication, and acquires tag information including an electronic product code. For example, when the wireless communication terminal equipped with the RFID reader adopts an ISO/IEC 18000-6C International Standard Specification, the RFID reader 220 acquires the tag information including an electronic product code through the procedure of ‘Select,’ ‘Inventory,’ and ‘Access.’ The RFID tag 110 interprets the read command by using the energy of a signal transmitted from the reader and makes a response through back-scattering modulation.

The controller 230 inquires the object directory server 150 for the position of the contents server 160, which includes contents information related to the tag, through the mobile communication network and the Internet based on the tag information including an electronic product code transmitted from the RFID reader 220. Upon receipt of the request for the CS position information, the object directory server 150 transmits the CS position information including the contents corresponding to the electronic product code to the wireless communication terminal through the mobile communication network and the Internet. Subsequently, the wireless communication terminal requests the contents server 160 of the received CS position information for service contents information corresponding to the tag information including the electronic product code through the mobile communication network and the Internet, receives the service contents information from the contents server 160, collects the service contents information, and displays the result on the display 270.

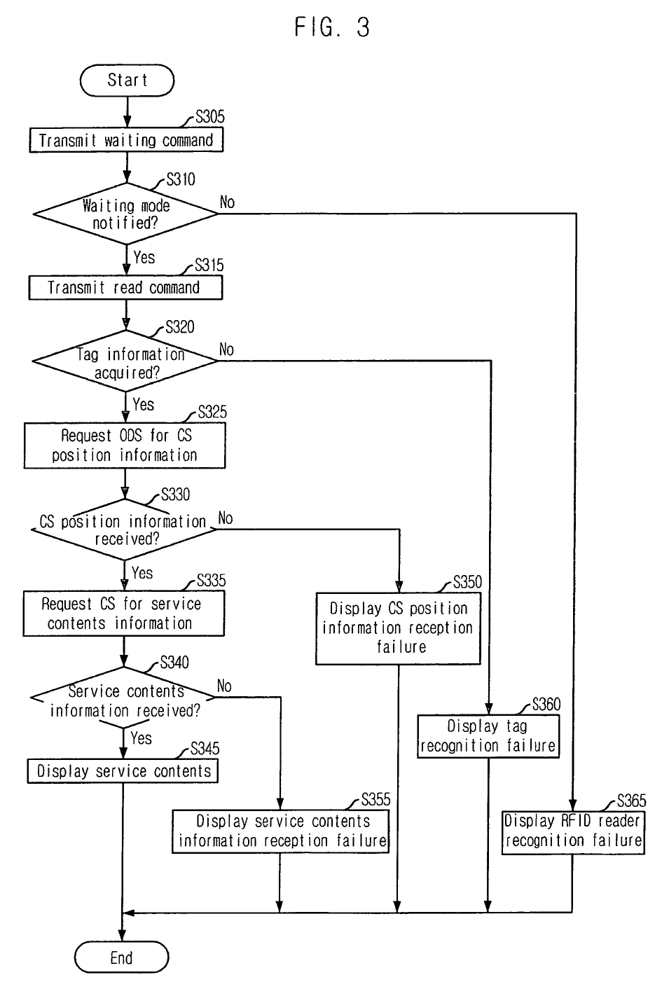

FIG. 3 is a flowchart describing an operation of a wireless communication terminal for a mobile RFID service. Referring to FIG. 3, the operation of the controller 230 of the wireless communication terminal for a mobile RFID service will be described hereinafter.

First, when an RFID menu is selected through the keypad, at step S305, the controller 230 transmits a waiting command to the RFID reader 220. When the controller 230 does not receive a notification that the RFID reader 220 is normally switched into a waiting mode, at step S365, the controller 230 displays an RFID reader recognition failure on the display 270. When the controller 230 receives a notification that the RFID reader 220 is normally switched into a waiting mode, at step S315, the controller 230 transmits a read command to the RFID reader 220 to execute an operation for reading tag information.

When the controller 230 does not receive tag information acquired from the reader-to-tag communication, at step S360, the controller 230 displays a tag recognition failure on the display 270. When the controller 230 receives tag information including an electronic product code from the RFID reader 220, at step S325, the controller 230 analyzes and processes the tag information and requests the object directory server 150 for CS position information.

When the controller 230 does not receive CS position information from the object directory server 150, at step S350, the controller 230 displays a CS position information reception failure on the display 270. When the controller 230 receives CS position information from the object directory server 150, at step S350, the controller 230 requests a contents server 160 corresponding to the CS position information for service contents information.

When the controller 230 does not receive service contents information from the contents server 160, at step S355, the controller 230 displays a service contents information reception failure on the display 270. When the controller 230 receives service contents information from the contents server 160, at step S345, the controller 230 collects received information and displays the result, i.e., service contents, on the display 270.

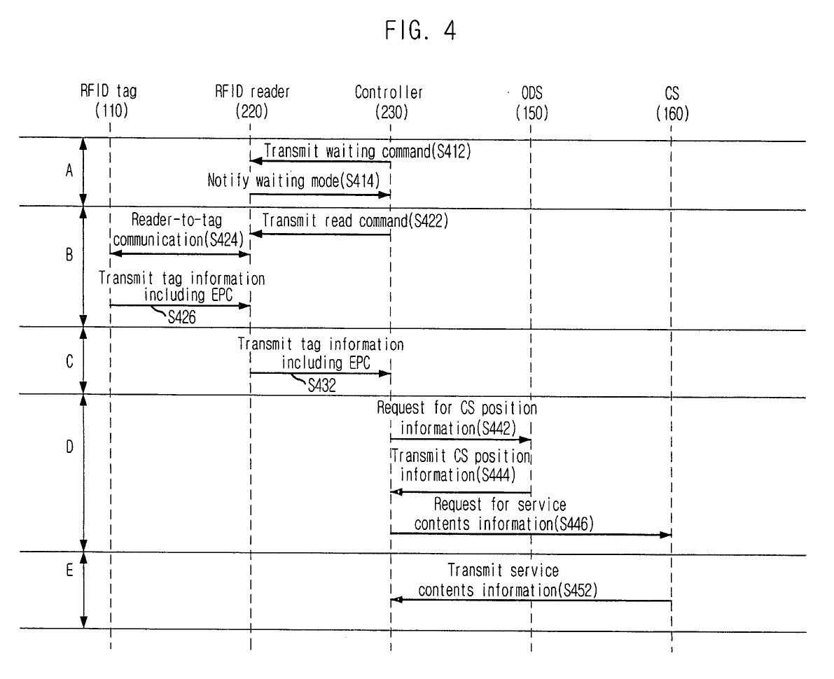

The call reception processing method suggested in the embodiment of the present invention is different according to when a call is received in the execution steps of the mobile RFID service. FIG. 4 is a view illustrating a method of processing a reception call according to when the call is received in the steps of a mobile RFID service processing which is divided into five durations in accordance with an embodiment of the present invention.

As shown in FIG. 4, the mobile RFID service process is divided into five durations and the call reception in the middle of a mobile RFID service occurs in any one of the five durations. A duration A is when a call is received before the controller 230 transmits a read command to the RFID reader 220 for a reader-to-tag communication. A duration B is when a call is received after the controller 230 transmits the read command but does not receive tag information yet from the RFID reader 220. A duration C is when a call is received when the controller 230 has received the tag information but has not requested the object directory server 150 for CS position information yet. A duration D is when a call is received when the controller 230 has requested for the CS position information but has not received service contents information from a contents server 160 yet. A duration E is when a call is received after the controller 230 has received the service contents information from the contents server 160. Call processing is different according to when a call is received among the five durations. Hereinafter, call processing methods in the above durations will be described.

First, when a call is received in the duration A when the controller 230 has not transmitted a read command to the RFID reader 220 yet, the controller 230 has not finished basic setup of the RFID reader 220 yet. Thus, the power applied to the RFID reader 220 is turned off to thereby cancel the RFID function, and the call reception process is performed. Through this operation, the wireless communication terminal can reduce wasteful power consumption. Since the RFID reader 220 is not normally operated yet, it does not have to display a message on the display 270 before or after the call reception.

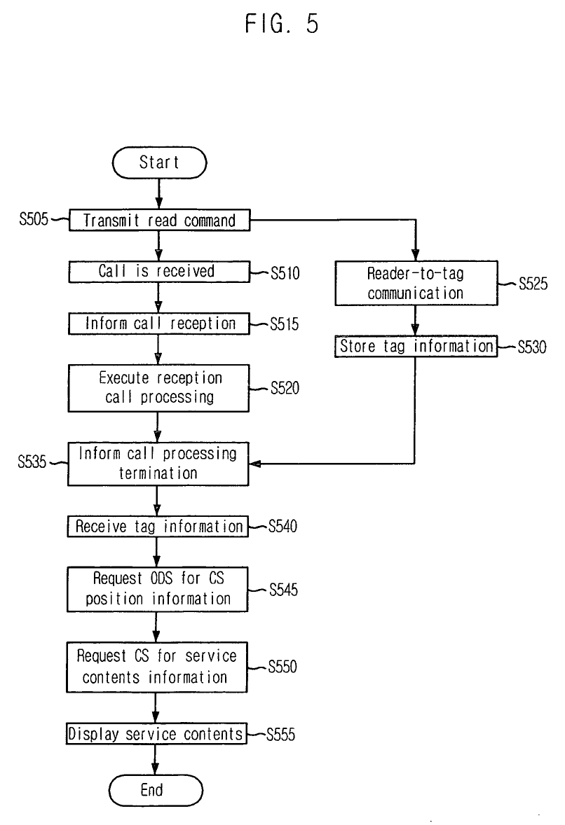

Call reception in the duration B after the controller 230 has transmitted the read command but has not received tag information yet from the RFID reader 220 will be described with reference to FIG. 5. Since the RFID reader 220 can perform reader-to-tag communication independently from the controller 230, the RFID reader 220 acquires tag information including an electronic product code from the reader-to-tag communication, stores the acquired tag information in the memory (not shown) of the RFID reader 220, and waits until it receives a notification that call is terminated from the controller 230 at steps S525 and S530. In the meantime, the controller 230 processes a reception call independently from the RFID reader 220 at steps S510 and S515, S520, and when the reception call processing is terminated, it transmits a call processing termination notification signal to the RFID reader 220 at step S535. Upon receipt of the call processing termination notification signal, the RFID reader 220 transmits the tag information stored in the memory of the RFID reader to the controller 230 at step S540. The controller 230 receives the tag information and performs the subsequent RFID service operations described in the above with reference to FIGS. 1 and 3. That is, at step S545, the controller 230 requests the object directory server 150 for CS position information. At step S550, the controller 230 requests the contents server 160 for service contents information. At step S555, the controller 230 shows the service contents on the display 270. Meanwhile, when there is no tag information stored in the memory of the RFID reader, the controller 230 displays a tag information acquisition failure on the display 270.

When a call is received in the duration C when the controller 230 has received the tag information but has not requested the object directory server 150 for CS position information yet, the controller 230 turns off the power of the RFID reader 220, stores the received tag information in the terminal memory 240, and processes the reception call. Also, when the reception call processing is terminated, the controller 230 performs the subsequent RFID service operations described in the above with reference to FIGS. 1 and 3 by using the tag information stored in the terminal memory 240.

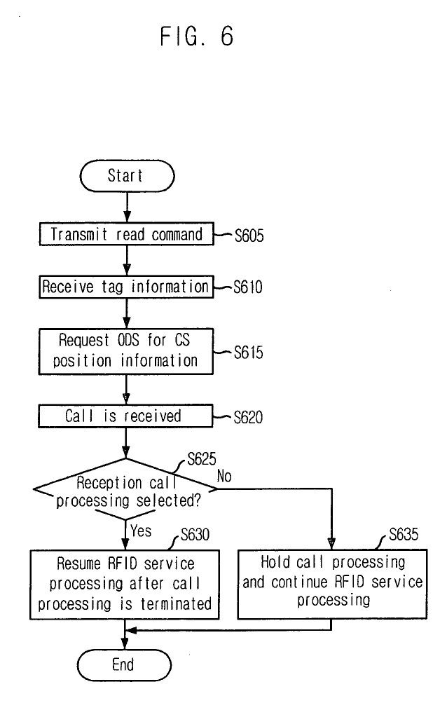

Reception call processing in the duration D when a call is received when the controller 230 has requested for the CS position information but has not received service contents information from the contents server 160 yet will be described with reference to FIG. 6. When a call is received in the circumstance that the RFID reader 220 has acquired tag information upon receipt of the read command and the controller 230 has requested the object directory server 150 for the CS position information based on the tag information at steps S605, S610, S615 and S620, the controller 230 has to perform only one between the mobile RFID service processing and reception call processing. Thus, when a call is received in the duration D, the controller 230 displays call reception on the display 270, displays an inquiry message asking which of the mobile RFID service processing and reception call processing will be selected on the display 270 and receives a user's selection information from the keypad at step S625.

When the user selects a reception call processing, the controller 230 stores the tag information in the terminal memory 240, holds back the mobile RFID service, and engages in the reception call processing. When the reception call processing is terminated, the controller 230 performs the RFID service procedure described in the above with reference to FIGS. 1 and 3 based on the stored tag information from the step of requesting the object directory server 150 for the CS position information. Herein, when a call is received after the controller 230 has received the CS position information from the object directory server 150, the controller 230 stores the received CS position information and tag information in the terminal memory 240, holds back the mobile RFID service. When the reception call processing is terminated, the controller 230 resumes the mobile RFID service processing from the step of requesting the contents server 160 for service contents information based on the tag information and the CS position information, which are stored in the terminal memory 240. Meanwhile, when the user selects the mobile RFID service processing to be continued, the controller 230 terminates reception call processing, and continuously performs the subsequent mobile RFID service processing at step S635.

Finally, when a call is received in the duration E after the controller 230 has received the service contents information from the contents server 160, the controller 230 stores the received service contents information in the terminal memory 240 and performs reception call processing. When the reception call processing is terminated, the controller 230 collects the stored service contents information and displays corresponding service contents on the display 270.

The method of the present invention can be realized as a program and stored in a computer-readable recording medium, such as CD-ROM, RAM, ROM, floppy disks, hard disks, magneto-optical disks and the like. Since the process can be easily implemented by those skilled in the art to which the present invention pertains, the process will not be described in detail herein.

The present invention provides a method for effectively processing a reception call in the middle of using a mobile RFID service, which is the first step to be processed when a mobile RFID service system is combined with a mobile communication network, and a wireless communication terminal employing the method.

Also, the present invention not only resolves a problem of collision between a reception call processing and a mobile RFID service processing but also reduces a reception call processing time and a mobile RFID service processing time in a wireless communication terminal by processing a reception call appropriately to each duration of the mobile RFID service processing.

The present application contains subject matter related to Korean patent application Nos. 2005-0116124 and 2006-0042577, filed in the Korean Intellectual Property Office on Dec. 1, 2005, and May 11, 2006, respectively, the entire contents of which is incorporated herein by reference.

While the present invention has been described with respect to certain preferred embodiments, it will be apparent to those skilled in the art that various changes and modifications may be made without departing from the scope of the invention as defined in the following claims.

What is claimed is:

1. A wireless communication terminal capable of providing a mobile radio frequency identification (RFID) service, comprising:
an RFID reader configured to acquire tag information through communication with an RFID tag;
a controller configured to request an object directory server (ODS) for contents server (CS) position information based on the tag information transmitted from the RFID reader and request a contents server for service contents information based on the tag information and the CS position information transmitted from the object directory server; and
a terminal memory configured to store the tag information,
wherein the controller performs control to avoid collision between a reception call processing and a mobile RFID service processing according to when a call is received in the steps of the mobile RFID service processing.

2. The wireless communication terminal as recited in claim 1, wherein when a call is received before the controller transmits a read command for initiating communication with the RFID tag to the RFID reader, the controller turns off power applied to the RFID reader and engages in the reception call processing.

3. The wireless communication terminal as recited in claim 1, wherein when the call is received before the controller receives the tag information from the RFID reader which has received the read command for initiating communication with the RFID tag, the controller receives the tag information from the RFID reader after processing the reception call.

4. The wireless communication terminal as recited in claim 3, wherein the RFID reader includes a reader memory configured to store tag information, which is acquired from the communication with the RFID tag, when the RFID reader receives the read command followed by call reception notification from the controller.

5. The wireless communication terminal as recited in claim 1, wherein when a call is received before the controller requests the object directory server for CS position information based on the tag information transmitted from the RFID reader, the controller processes the reception call and then requests the object directory server for the CS position information.

6. The wireless communication terminal as recited in claim 1, wherein when a call is received before the controller receives service contents information from the contents server after requesting the object directory server for the CS position information, the controller executes an operation selected by a terminal user between the reception call processing and the mobile RFID service processing.

7. The wireless communication terminal as recited in claim 1, wherein when a call is received before the controller receives service contents information from the contents server after requesting the object directory server for the CS position information, the controller terminates the mobile RFID service and engages in the reception call processing.

8. The wireless communication terminal as recited in claim 7, wherein when a call is received after the controller receives CS position information from the object directory server, the controller stores the received CS position information in the terminal memory and terminates the mobile RFID service processing.

9. The wireless communication terminal as recited in claim 1, wherein when a call is received after the controller receives service contents information from the contents server, the controller stores the received service contents information in the terminal memory and processes the reception call.

10. A method for processing a reception call in a wireless communication terminal while processing a mobile radio frequency identification (RFID) service, comprising the steps:
a) acquiring tag information through communication between an RFID reader and a RFID tag;
b) requesting an object directory server for CS position information based on the tag information; and
c) requesting a contents server for service contents information based on the CS position information transmitted from the object directory server and the tag information,
wherein when a call is received before the CS position information is requested to the object directory server based on the tag information, the CS position information is requested after reception call processing is terminated.

11. The method as recited in claim 10, wherein when a call is received before the CS position information is requested to the object directory server based on the tag information, the reception call processing is executed through the steps of:
e) storing the tag information in a terminal memory of the wireless communication terminal; and
f) requesting the object directory server for the CS position information based on the tag information stored the terminal memory after the reception call processing is terminated.

12. The method as recited in claim 10, wherein when the call is received before a read command for initiating the communication between the RFID reader and the RFID tag is transmitted to the RFID reader, power supplied to the RFID reader is turned off and then the reception call is processed.

13. The method as recited in claim 10, wherein when a call is received before the tag information is transmitted from the RFID reader which has received the read command for initiating the communication with the RFID tag, the reception call is processed and then the tag information is transmitted from the RFID reader.

14. The method as recited in claim 13, wherein when a call is received before the tag information is transmitted from the RFID reader which has received the read command for initiating the communication with the RFID tag, the reception call is processed through the steps of:
g) transmitting a call reception notification signal for informing the reception of a call from a controller of the wireless communication terminal to the RFID reader;
h) storing the tag information acquired from the communication between the RFID reader and the RFID tag in a reader memory of the RFID reader;
i) transmitting a call processing termination notification signal for informing that the reception call processing is terminated from the controller to the RFID reader; and
j) transmitting the tag information stored in the reader memory of the RFID reader to the controller.

15. The method as recited in claim 10, wherein when a call is received before the service contents information is transmitted from the contents server after CS position information is requested to the object directory server, any one between the reception call processing and the mobile RFID service processing is selected by a terminal user and executed.

16. The method as recited in claim 10, wherein when a call is received before the service contents information is transmitted from the contents server after CS position information is requested to the object directory server, the mobile RFID service processing is suspended and the reception call processing is executed.

17. The method as recited in claim 16, wherein when a call is received before the service contents information is transmitted from the contents server after CS position information is requested to the object directory server, the reception call processing is executed through the steps of:
k) storing the tag information transmitted from the RFID reader in a terminal memory of the wireless communication terminal; and
l) requesting the object directory server for CS position information based on the tag information stored in the terminal memory after the reception call processing is terminated.

18. The method as recited in claim 16, wherein when a call is received after the CS position information is transmitted from the object directory server, the CS position information is stored in the terminal memory of the wireless communication terminal and the mobile RFID service processing is suspended.

19. The method as recited in claim 18, wherein the reception call processing is executed through the steps of:
k) storing the tag information transmitted from the RFID reader and the CS position information in the terminal memory of the wireless communication terminal; and
l) requesting the contents server for service contents information based on the tag information and the CS position information stored in the terminal memory after the reception call processing is terminated.

20. The method as recited in claim 10, wherein when a call is received after the service contents information is transmitted from the contents server, the service contents information is stored in the terminal memory of the wireless communication terminal and the reception call processing is terminated.
